(19) United States
(12) Patent Application Publication
(10) Pub. No.: US 2026/0057948 A1
(43) Pub. Date: Feb. 26, 2026

(54) METHOD AND NON-TRANSITORY COMPUTER-READABLE STORAGE MEDIUM AND APPARATUS FOR CALIBRATING SIGNALS WITH FLASH INTERFACE

(71) Applicant: Silicon Motion, Inc., Zhubei City, Hsinchu County (TW)

(72) Inventor: Cheng-Yan CHENG, New Taipei City (TW)

(73) Assignee: Silicon Motion, Inc., Zhubei City, Hsinchu County (TW)

(21) Appl. No.: 19/091,605

(22) Filed: Mar. 26, 2025

(30) Foreign Application Priority Data
Aug. 21, 2024 (CN) 202411147827.5

(51) Int. Cl. G11C 16/32; G11C 16/20; G11C 16/28

(52) U.S. Cl. CPC G11C 16/32; G11C 16/20; G11C 16/28; G11C 2207/2254

(57) ABSTRACT

The invention introduces a method for calibrating signals with a flash interface, performed by a processing unit of a flash controller, to include: directing data transfer between the flash controller and the flash module to operate at a first speed; executing a first search algorithm to generate a first eye diagram for successfully completing data transmission under the first speed; obtaining a second reference voltage and a second time offset that are closet to a center point of the first eye diagram; directing data transfer between the flash controller and the flash module to operate at a second speed; executing a second search algorithm to generate a second eye diagram for successfully completing data transmission under the second speed; obtaining a third reference voltage and a third time offset that are closet to a center point of the second eye diagram as calibrated ones.

### CROSS-REFERENCE TO RELATED APPLICATIONS

This application claims the benefit of priority to Patent Application No. 202411147827.5, filed in China on Aug. 21, 2024; the entirety of which is incorporated herein by reference for all purposes.

### BACKGROUND

The disclosure generally relates to storage devices and, more particularly, to a method, a non-transitory computer-readable storage medium and an apparatus for calibrating signals with a flash interface.

Flash memory devices typically include NOR flash devices and NAND flash devices. NOR flash devices are random access—a host side accessing a NOR flash device can provide the device any address on its address pins and immediately retrieve data stored in that address on the device's data pins. NAND flash devices, on the other hand, are not random access but serial access. It is not possible for NAND to access any random address in the way described above. Instead, the host side has to write into the device a sequence of bytes which identifies both the type of command requested (e.g. read, write, erase, etc.) and the address to be used for that command. The address identifies a page (the smallest chunk of flash memory that can be written in a single operation) or a block (the smallest chunk of flash memory that can be erased in a single operation), and not a single byte or word. How to improve the access performance of NAND flash memory has always been an important issue for NAND controllers.

### SUMMARY

In an aspect of the invention, an embodiment introduces a method for calibrating signals with a flash interface (I/F), performed by a processing unit of a flash controller, to include the following steps: directing a data transmission between the flash controller and a flash module to operate under a first speed; executing a first search algorithm starting from a first reference voltage and a first time offset with driving of the flash I/F to generate a first eye diagram comprising combinations of reference voltages and time offsets that the flash I/F successfully completes the data transmission therebetween under the first speed; calculating a center point of the first eye diagram; obtaining a second reference voltage and a second time offset closet to the center point of the first eye diagram; directing the data transmission between the flash controller and the flash module to operate under a second speed; executing a second search algorithm starting from the second reference voltage and the second time offset with driving of the flash I/F to generate a second eye diagram comprising combinations of reference voltages and time offsets that the flash I/F successfully completes the data transmission therebetween under the second speed; calculating a center point of the second eye diagram; obtaining a third reference voltage and a third time offset closet to the center point of the second eye diagram as a calibrated reference voltage and a calibrated time offset; and storing the calibrated reference voltage and the calibrated time offset in nonvolatile space of a device side, thereby enabling the device side in runtime to configure the flash I/F accordingly for performing a high-speed data transmission. The second speed is higher than the first speed.

In another aspect of the invention, an embodiment introduces a non-transitory computer-readable storage medium having stored therein program code that, when loaded and executed by a processing unit, causes the processing unit to perform the method for calibrating signals with a flash I/F as described above.

In still another aspect of the invention, an embodiment introduces an apparatus for calibrating signals, to include: a flash interface (I/F), coupled to a flash module; and a processing unit, coupled to the flash I/F. The processing unit is arranged operably to: direct a data transmission between the flash controller and a flash module to operate under a first speed; execute a first search algorithm starting from a first reference voltage and a first time offset with driving of the flash I/F to generate a first eye diagram comprising combinations of reference voltages and time offsets that the flash I/F successfully completes the data transmission therebetween under the first speed; calculate a center point of the first eye diagram; obtain a second reference voltage and a second time offset closet to the center point of the first eye diagram; direct the data transmission between the flash controller and the flash module to operate under a second speed; execute a second search algorithm starting from the second reference voltage and the second time offset with driving of the flash I/F to generate a second eye diagram comprising combinations of reference voltages and time offsets that the flash I/F successfully completes the data transmission therebetween under the second speed; calculate a center point of the second eye diagram; obtain a third reference voltage and a third time offset closet to the center point of the second eye diagram as a calibrated reference voltage and a calibrated time offset; and store the calibrated reference voltage and the calibrated time offset in nonvolatile space of a device side, thereby enabling the device side in runtime to configure the flash I/F accordingly for performing a high-speed data transmission. The second speed is higher than the first speed.

Both the foregoing general description and the following detailed description are examples and explanatory only, and are not restrictive of the invention as claimed.

### BRIEF DESCRIPTION OF THE DRAWINGS

FIG. 1 is the system architecture of an electronic apparatus according to an embodiment of the invention.

FIG. 2 is a schematic diagram illustrating a flash module according to an embodiment of the invention.

FIG. 3 is a schematic diagram showing the hardware architecture of a portion of a NAND flash unit according to an embodiment of the invention.

FIG. 4 is a timing diagram for reading data from a flash module according to an embodiment of the invention.

FIG. 5 is a timing diagram for writing data into a flash module according to an embodiment of the invention.

FIG. 6 is a schematic diagram for calibrating a flash interface (I/F) according to an embodiment of the invention.

FIG. 7 illustrates eye diagrams each including a calibrated reference voltage and a calibrated time offset according to some implementations.

FIG. 8 illustrates eye diagrams generated in extreme manufacturing deviations according to some implementations.

FIG. 9 is a flowchart illustrating a method for calibrating signals with a flash I/F in data reads according to an embodiment of the invention.

FIG. 10 is a flowchart illustrating a method for calibrating signals with a flash I/F in data writes according to an embodiment of the invention.

FIG. 11 illustrates eye diagrams generated in extreme manufacturing deviations according to an embodiment of the invention.

### DETAILED DESCRIPTION

Reference is made in detail to embodiments of the invention, which are illustrated in the accompanying drawings. The same reference numbers may be used throughout the drawings to refer to the same or like parts, components, or operations.

Certain aspects and embodiments of this disclosure are provided below. Some of these embodiments may be applied independently and some of them may be applied in conjunction as would be apparent to those of skill in the art. In the following description, for the purposes of explanation, specific details are set forth in order to provide a thorough understanding of aspects of the application. However, it will be apparent that various embodiments may be practiced without these specific details. The figures and description are not intended to be restrictive.

The ensuing description provides example aspects only, and is not intended to limit the scope, applicability, or configuration of the disclosure. Rather, the ensuing description of the example aspects will provide those skilled in the art with an enabling description for implementing an example aspect. It should be understood that changes may be made in the function and arrangement of elements without departing from the spirit and scope of the application as set forth in the claims.

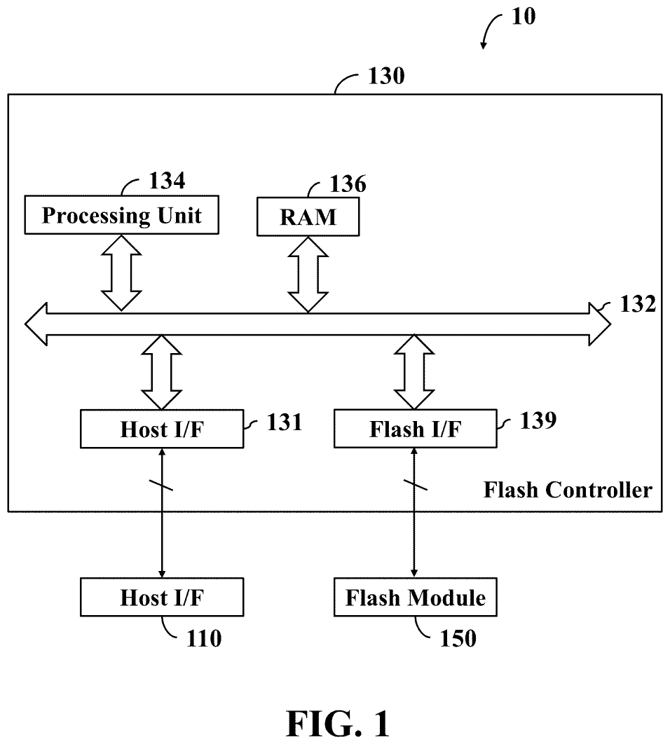

Refer to FIG. 1. The electronic apparatus 10 includes the host side 110, the flash controller 130 and the flash module 150, and the flash controller 130 and the flash module 150 can be collectively referred to as a device side. The electronic apparatus 10 may be included in an external storage device, a Personal Computer (PC), a laptop PC, a tablet PC, a mobile phone, a digital camera, a digital recorder, a smart television, a smart freezer, an automotive electronics system or other consumer electronic products. The host side 110 and the host interface (I/F) 131 of the flash controller 130 may communicate with each other by Universal Serial Bus (USB), Advanced Technology Attachment (ATA), Serial Advanced Technology Attachment (SATA), Peripheral Component Interconnect Express (PCI-E), Universal Flash Storage (UFS), Embedded Multi-Media Card (eMMC) protocol, or others. The flash I/F 139 of the flash controller 130 and the flash module 150 may communicate with each other by a Double Data Rate (DDR) protocol, such as Open NAND Flash Interface (ONFI), DDR Toggle, or others. The flash controller 130 includes the processing unit 134 and the processing unit 134 may be implemented in numerous ways, such as with general-purpose hardware (e.g., a microcontroller unit, a single processor, multiple processors or graphics processing units capable of parallel computations, or others) that is programmed using firmware and/or software instructions to perform the functions recited herein. The processing unit 134 may receive host commands from the host side 110 through the host interface (I/F) 131, such as write commands, read commands, discard commands, erase commands, etc., schedule and execute the host commands. The flash controller 130 includes the Random Access Memory (RAM) 136, which may be implemented in a Dynamic Random Access Memory (DRAM), a Static Random Access Memory (SRAM), or the combination thereof, for allocating space as a data buffer storing user data (also referred to as host data) that has been obtained from the host side 110 and is to be programmed into the flash module 150, and that has been read from the flash module 150 and is to be output to the host side 110. The RAM 136 stores necessary data in execution, such as variables, data tables, data abstracts, host-address to flash-address mapping (H2F) tables, flash-address to host-address mapping (F2H) tables, or others. The flash I/F 139 includes a NAND flash controller (NFC) to provide functions that are required to access to the flash module 150, such as a command sequencer, a Low Density Parity Check (LDPC) encoder/decoder, etc.

The flash controller 130 may be equipped with the bus architecture 132 to couple components to each other to transmit data, addresses, control signals, etc. The components include but not limited to the host I/F 131, the processing unit 134, the RAM 136 and the flash I/F 139. A direct memory access (DMA) circuitry of a component moves data between specific components through the bus architecture 132 according to instructions or control signals. For example, a DMA circuitry of the host I/F 131 or the flash I/F 139 may migrate data in a specific data buffer thereof to a specific address of the RAM 136, migrate data in a specific address of the RAM 136 to a specific data buffer thereof, and so on.

The flash module 150 provides huge storage space typically in hundred Gigabytes (GBs), or even several Terabytes (TBs), for storing a wide range of user data, such as high-resolution images, video files, etc. The flash module 150 includes control circuitries and memory arrays containing memory cells, such as being configured as Single Level Cells (SLCs), Multi-Level Cells (MLCs), Triple Level Cells (TLCs), Quad-Level Cells (QLCs), or any combinations thereof. The processing unit 134 programs user data into a designated address (a destination address) of the flash module 150 and reads user data from a designated address (a source address) thereof through the flash I/F 139. The flash I/F 139 may use several electronic signals including a data line, a clock signal line and control signal lines for coordinating the command, address and data transfer with the flash module 150. The data line may be used to transfer commands, addresses, read data and data to be programmed; and the control signal lines may be used to transfer control signals, such as Chip Enable (CE), Address Latch Enable (ALE), Command Latch Enable (CLE), Write Enable (WE), strobe, etc.

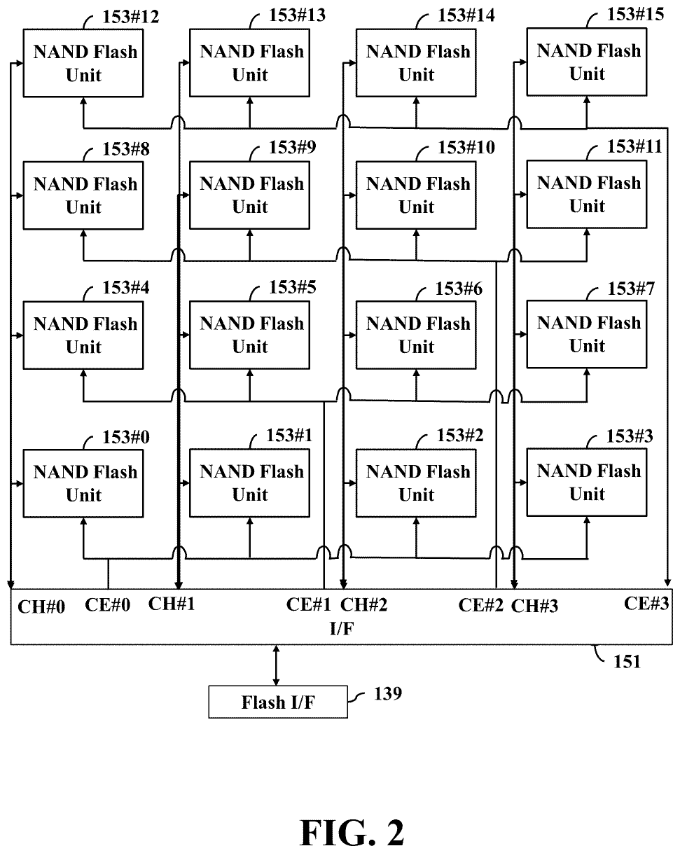

Refer to FIG. 2. The I/F 151 of the flash module 150 may include four I/O channels (hereinafter referred to as channels) CH#0 to CH#3 and each is connected to four NAND flash units, for example, the channel CH#0 is connected to the NAND flash units 150#0, 150#4, 150#8 and 150#12. Each NAND flash unit can be packaged in an independent die. The flash I/F 139 may issue one of the CE signals CE#0 to CE#3 through the I/F 151 to activate the NAND flash units 153#0 to 153#3, the NAND flash units 153#4 to 153#7 , the NAND flash units 153#8 to 153#11, or the NAND flash units 153#12 to 153#15, and read data from or program data into the activated NAND flash units in parallel.

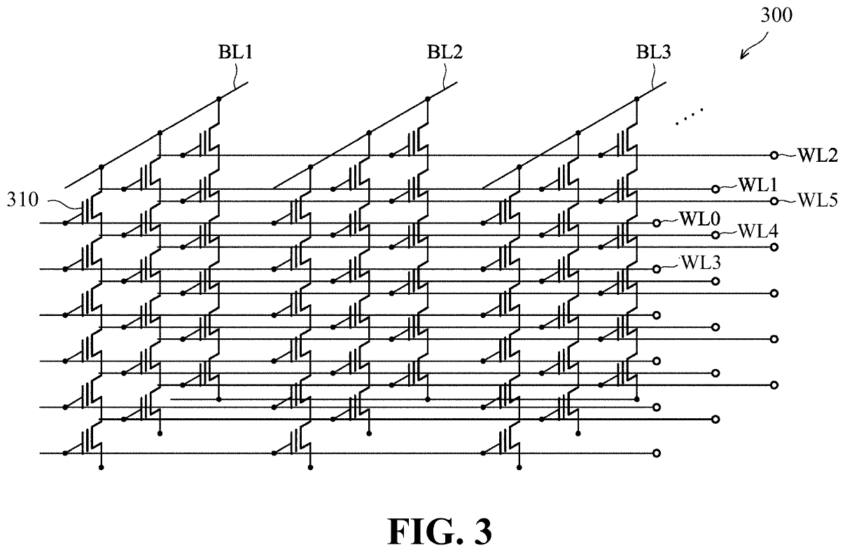

Refer to FIG. 3 showing the hardware architecture of a portion of a NAND flash unit. Each NAND flash unit may contain a plurality of memory blocks (e.g. the memory block 300) and the memory block 300 contains multiple memory cells, such as floating gate transistors (e.g. the floating gate transistor 310), or other charge trap devices. The structure of the memory block 300 includes bit lines and word lines. For brevity, only the bit lines BL1 to BL3 and the word lines WL0 to WL5 are labeled in FIG. 3. For example, the floating gate transistors on each of the word lines WL0 to WL2 and WL3 to WL5 store data on one or more pages.

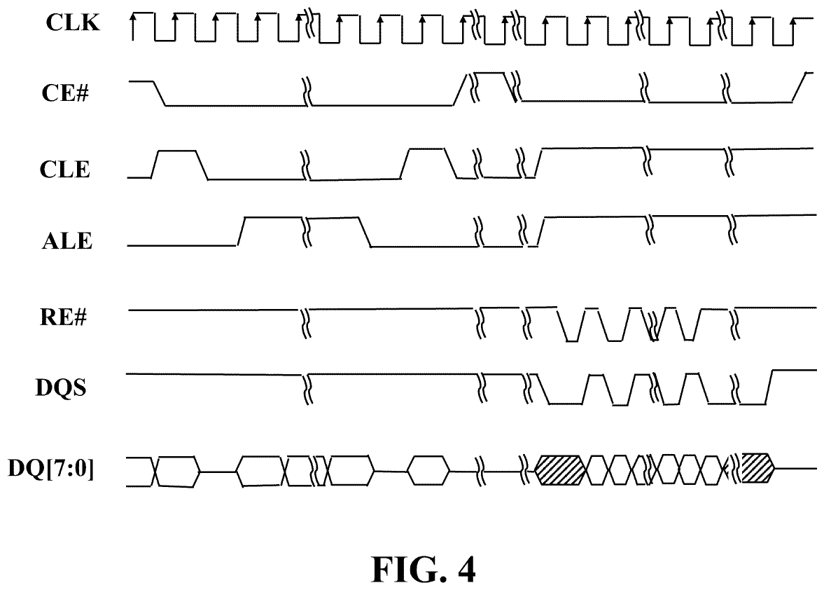

To read data from the flash module 150, refer to FIG. 4 showing the timing diagram for reading data from the flash module 150. The signals in the figure are described as follows:
CLK: Clock. The clock signal is generated by the flash I/F 139. Transitions are triggered on both the rising and falling edges of CLK to implement DDR protocol.
DQ[7:0]: Data buses.
CLE: The flash I/F 139 uses data buses DQ[7:0] to send read commands to the flash module 150 when CLE is active.
ALE: The flash I/F 139 uses data buses DQ[7:0] to send read addresses to the flash module 150 when ALE is active.
CE#: The signal is used to select a specific chip to read.
RE#: The flash I/F 139 generates the signal that is sent to the flash module 150. Each time the signal is toggled, the flash module 150 prepares data on the data buses DQ[7:0] for the flash I/F 139 to read.
DQS: Data Strobe. DQS is generated by the flash module 150 and is used to distinguish each data transmission period, so that the flash I/F 139 can receive data accurately. DQS can be regarded as a synchronization signal of data. The flash I/F 139 can receive data on the data buses DQ[7:0] once detecting the rising and falling edges of DQS.

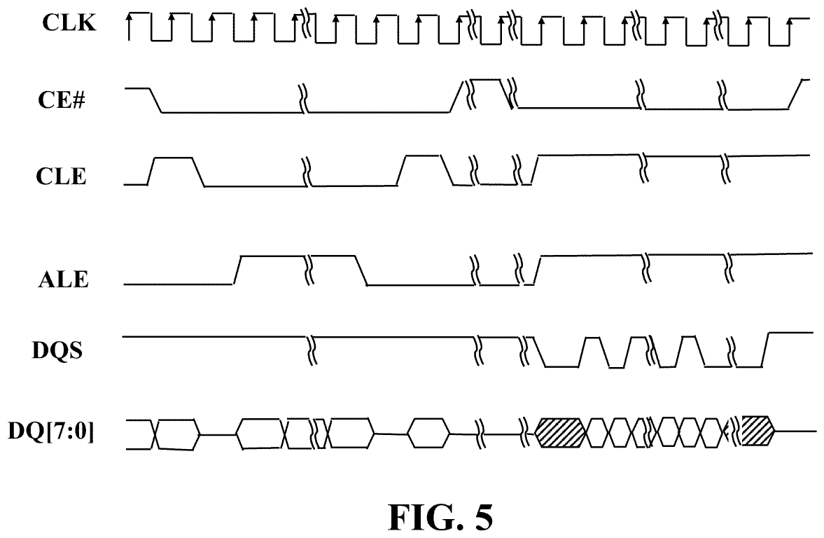

To program data into the flash module 150, refer to FIG. 5 showing the timing diagram for programing data into the flash module 150. The signals in the figure are described as follows:
CLK: Clock. The clock signal is generated by the flash I/F 139. Transitions are triggered on both the rising and falling edges of CLK to implement DDR protocol.
DQ[7:0]: Data buses.
CLE: The flash I/F 139 uses data buses DQ[7:0] to send write commands to the flash module 150 when CLE is active.
ALE: The flash I/F 139 uses data buses DQ[7:0] to send write addresses to the flash module 150 when ALE is active.
CE#: The signal is used to select a specific chip to write.
DQS: Data Strobe. DQS is generated by the flash I/F 139 and is used to distinguish each data transmission period, so that the flash module 150 can receive data accurately. DQS can be regarded as a synchronization signal of data. The flash module 150 can receive data on the data buses D[7:0] once detecting the rising and falling edges of DQS.

In order to ensure that the data transmission and reception between the flash I/F 139 and the flash module 150 stably meet the requirements of high-speed transmission (for example, higher than 1200 MHz), during mass production, or during device-side initialization, the processing unit 134 needs to calibrate the flash I/F 139. The calibration of flash I/F 139 includes the data read calibration and the data write calibration.

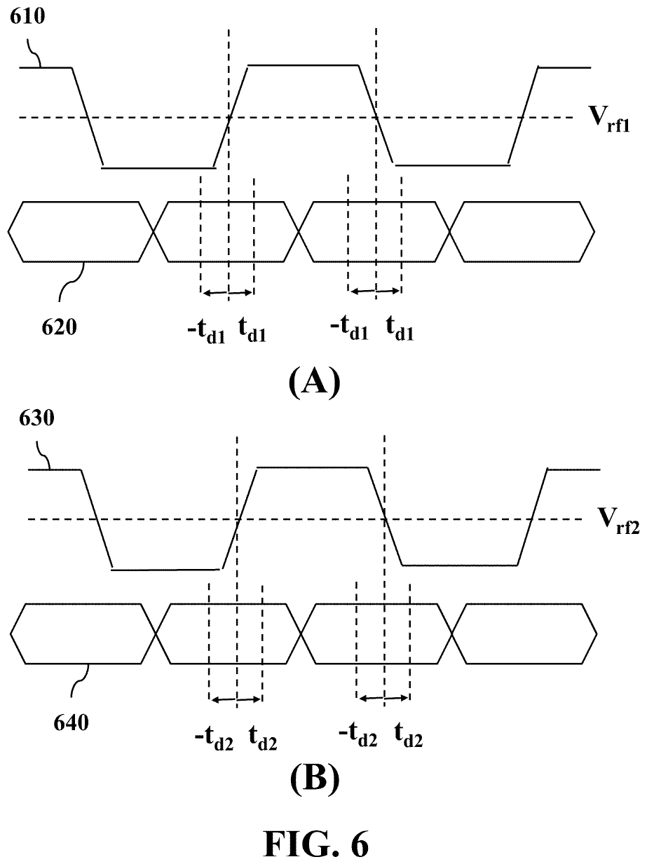

Refer to FIG. 6 showing a schematic diagram of the calibration for the flash I/F 139. Regarding the calibration for data reads as shown in the upper part (A), it includes the calibration of the reference voltage V_{rf1} and the time offset t_{d1}. The reference voltage V_{rf1} represents the average voltage of DQS 610 transmitted from the flash module 150 to the flash I/F 139. For example, when the reference voltage V_{rf1} is set to 0.2V, the high voltage of DQS 610 is 0.4V and the low voltage of DQS 610 is 0V. The time offset t_{d1} represents a period of time after each rising edge or falling edge of DQS 610, and the time offset −t_{d1} represents a period of time before each rising edge or falling edge of DQS 610. Input components in the flash I/F 139 stores the data on the data bus DQ[7:0] 620 in the input buffer of the flash I/F 139 at each time point corresponding to the time offset t_{d1} or −t_{d1}. The calibrated reference voltage V_{rf1} and the calibrated time offset t_{d1} or −t_{d1} are stored in nonvolatile storage space, such as the designated address of the SRAM, or the designated system page in the flash module 150, so that the device side in runtime can configure the flash module 150 and the flash I/F 139 accordingly for performing high-speed data reading.

Regarding the calibration for data write as shown in the lower part (B), it includes the calibration of the reference voltage V_{rf2} and the time offset t_{d2}. The reference voltage V_{rf2} represents the average voltage of DQS 630 transmitted from the flash I/F 139 to the flash module 150. For example, similarly, when the reference voltage V_{rf2} is set to 0.2V, the high voltage of DQS 630 is 0.4V and the low voltage of DQS 630 is 0V. The time offset t_{d2} represents a period of time after each rising edge or falling edge of DQS 630, and the time offset −t_{d2} represents a period of time before each rising edge or falling edge of DQS 630. Output components in the flash I/F 139 puts the data in the output buffer of the flash I/F 139 on the data bus DQ[7:0] 640 to transmit it to the flash module 150 at each time point corresponding to the time offset t_{d2} or −t_{d2}. The calibrated reference voltage V_{rf2} and the calibrated time offset t_{d2} or −t_{d2} are stored in nonvolatile storage space, such as the designated address of the SRAM, or the designated system page in the flash module 150, so that the device side in runtime can configure the flash module 150 and the flash I/F 139 accordingly for performing high-speed data programming.

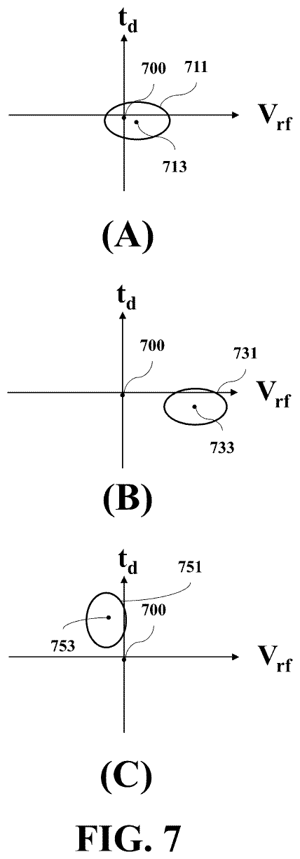

In order to obtain the reference voltage V_{rf1} and the time offset t_{d1} or −t_{d1} for the high-speed reception, in some implementations, the processing unit 134 executes a search algorithm starting from a predefined reference voltage and a predefined time offset to depict an eye diagram including all combinations of the reference voltages and the time offsets that the flash I/F 139 can successfully receive data from the flash module 150, and then obtains the reference voltage and the time offset corresponding to the center point of the eye diagram as the calibrated reference voltage and the calibrated time offset corresponding to data read operations. In order to obtain the reference voltage V_{rf2} and the time offset t_{d2} or −t_{d2} for the high-speed transmission, in some implementations, the processing unit 134 executes a search algorithm starting from a predefined reference voltage and a predefined time offset to depict an eye diagram including all combinations of the reference voltages and the time offsets that the flash I/F 139 can successfully transmit data to the flash module 150, and then obtains the reference voltage and the time offset corresponding to the center point of the eye diagram as the calibrated reference voltage and the calibrated time offset corresponding to data write operations. In the case where the eye diagram contains a combination of the predefined voltage and the predefined time offset, the search algorithm can efficiently obtain the calibrated reference voltage and the calibrated time offset (for example, the reference voltage V_{rf1} and the time offset t_{d1} or −t_{d1} for data read operations, or the reference voltage V_{rf2} and the time offset t_{d2} or −t_{d2} for data write operations). For example, refer to part (A) in FIG. 7, the processing unit 134 depicts the eye diagram 711 starting from the predefined reference voltage and the predefined time offset 700 that can successfully transmit data to the flash module 150, and then, obtains the calibrated reference voltage and the calibrated time offset 713 corresponding to the center point of the eye diagram 711. Similarly, refer to part (B) in FIG. 7, the processing unit 134 obtains the calibrated reference voltage and the calibrated time offset 733 corresponding to the center point of the eye diagram 731. Refer to part (C) in FIG. 7, the processing unit 134 obtains the calibrated reference voltage and the calibrated time offset 753 corresponding to the center point of the eye diagram 751.

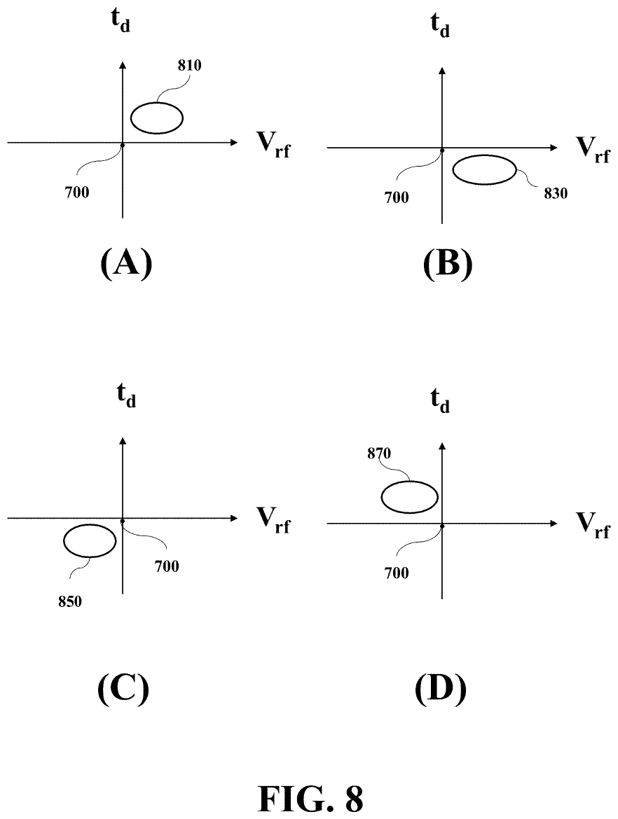

However, in the case of extreme manufacturing deviations (that is, the case where the eye diagram does not contain the combination of the predefined reference voltage and the predefined time offset), the search algorithm starting from the predefined reference voltage and the predefined time offset, as described above, would not be able to depict any eye diagram and make the entire calibration operation fail, or would take more time to scan all possible combinations of reference voltages and time offsets to obtain the eye diagram, the calibrated reference voltage and the calibrated time offset. For example, the dye diagram 810 in part (A) of FIG. 8 does not contain the point 700 of the predefined reference voltage and the predefined time offset. Similarly, the eye diagram 830 in part (B), the eye diagram 850 in part (C), and the eye diagram 870 in part (D) of FIG. 8 do not contain the point 700 of the predefined reference voltage and the predefined time offset.

In order to solve the problems occurred in extreme manufacturing deviations, an embodiment of the invention introduces the two-stage search mechanism suitable for the methods for calibrating signals with the flash I/F for data reads and data writes. The signal calibration methods of the flash I/F can be performed in the mass production process, or in the device initialization process by the device side during runtime. During the first stage, the processing unit 134 directs the data transmission between the flash controller 130 and the flash module 150 to operate under the low speed, executes the search algorithm starting from the predefined reference voltage and the predefined time offset with driving of the flash I/F 139 to generate the low-speed eye diagram including combinations of the reference voltages and the time offsets that the flash I/F 139 can successfully complete data transmission, calculates the center point of the low-speed eye diagram, and obtains the reference voltage and the time offset closet to the center point of the low-speed eye diagram as the initial reference voltage and the initial time offset. During the second stage, the processing unit 134 directs the data transmission between the flash controller 130 and the flash module 150 to operate under the high speed, executes the search algorithm starting from the initial reference voltage and the initial time offset with driving of the flash I/F 139 to generate the high-speed eye diagram including combinations of the reference voltages and the time offsets that the flash I/F 139 can successfully complete data transmission, calculates the center point of the high-speed eye diagram, and obtains the reference voltage and the time offset closet to the center point of the high-speed eye diagram as the calibrated reference voltage and the calibrated time offset. Finally, the calibrated reference voltage and the calibrated time offset are stored in non-volatile storage space of the device side, for example, the designated address of SRAM, or the designated system page in the flash module 150. The high speed may be six times or more than the low speed.

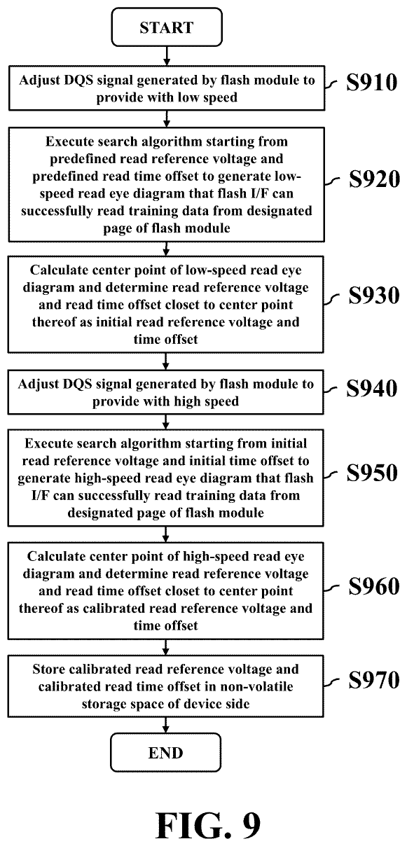

An embodiment of the invention introduces a method for calibrating signals with the flash I/F 139 for data reads, which is performed by the processing unit 134 when loading and executing calibration program code. Refer to the flowchart as shown in FIG. 9. Detailed descriptions are provided as follows:

Step S910: The DQS signal generated by the flash module 150 is adjusted to provide with a low speed. In some embodiments, refer to FIG. 4, the processing unit 134 controls the flash I/F 139 to output a low-speed RE# signal to the flash module 150, so that the flash module 150 accordingly generates a low-speed DQS signal. The low speed can be any frequency from 50 MHz to 200 MHz.

Step S920: The search algorithm starting from the predefined read reference voltage (for example, 0.2V) and the predefined read time offset (for example, 0 picosecond—ps) is executed to generate a low-speed read eye diagram including all combinations of reference voltages and time offsets that the flash I/F 139 can successfully read training data from the designated page of the flash module 150.

In an exemplary search algorithm, the processing unit 134 issues a set command to the flash module 150 through the flash I/F 139 for setting the reference voltage of DQS signal generated by the I/F 151 of the flash module 150 to the predefined read reference voltage, and setting the predefined read time offset to a delay-locked loop (DLL) circuitry of the flash I/F 139 for fetching data on the data bus DQ[7:0]. The set command can be SET FEATURE command “EFh” in the ONFI specification. The processing unit 134 issues the read command and the address to the flash module 150 through the flash I/F 139 to instruct the flash module 150 to read training data from the designated page, and then, obtains the training data on the data bus DQ[7:0] under the condition of the predefined read reference voltage and the predefined read time offset. The processing unit 134 determines whether the training data is correct. In some embodiments, if error bits included in the obtained training data can be corrected, then the obtained training data is judged as correct one. If the obtained training data is correct, let the search algorithm continue to execute. In very rare cases, the obtained training data is incorrect, indicating that there are critical manufacturing defects in the flash I/F 139 or the flash module 150, and the whole device side needs further inspection.

Subsequently, the processing unit 134 repeatedly executes a loop with the predefined read reference voltage until the training data cannot be read from the designated page in the flash module 150. In each iteration, the processing unit 134 increases the current read time offset by one step to generate a new read time offset, and sets the new read time offset to the DLL circuitry of the flash I/F 139 for fetching data on the data bus DQ[7:0]. Next, under the condition of the predefined read reference voltage and the new read time offset, the processing unit 134 obtains the training data on the data bus DQ[7:0] and determines whether the obtained training data is correct. Assume that the default frequency of DQS signal generated by the flash module 150 is 140 MHz, one step is 45 ps, and the read time offset can be increased to up to 8 steps: The processing unit 134 executes at most 8 iterations, in which the new read time offsets are 45 ps, 90 ps, 135 ps, and so on. The predefined read reference voltage and the last read time offset, which make the flash I/F 139 can read the training data correctly, form the upper-bound reference of the low-speed read eye diagram.

Subsequently, the processing unit 134 repeatedly executes a loop with the predefined read reference voltage until the training data cannot be read from the designated page in the flash module 150. In each iteration, the processing unit 134 decreases the current read time offset by one step to generate a new read time offset, and sets the new read time offset to the DLL circuitry of the flash I/F 139 for fetching data on the data bus DQ[7:0]. Next, under the condition of the predefined read reference voltage and the new read time offset, the processing unit 134 obtains the training data on the data bus DQ[7:0] and determines whether the obtained training data is correct. Assume that the default frequency of DQS signal generated by the flash module 150 is 140 MHz, one step is 45 ps, and the read time offset can be decreased to up to 8 steps: The processing unit 134 executes at most 8 iterations, in which the new read time offsets are −45 ps, −90 ps, −135 ps, and so on. The predefined read reference voltage and the last read time offset, which make the flash I/F 139 can read the training data correctly, form the lower-bound reference of the low-speed read eye diagram.

Subsequently, the processing unit 134 repeatedly executes a loop with the predefined read time offset until the training data cannot be read from the designated page in the flash module 150. In each iteration, the processing unit 134 increases the current read reference voltage by one step to generate a new read reference voltage, and issues the set command to the flash module 150 through the flash I/F 139 to adjust the reference voltage of DQS signal generated by the I/F 151 of the flash module 150 to the new read reference voltage. Next, under the condition of the new read reference voltage and the predefined read time offset, the processing unit 134 obtains the training data on the data bus DQ[7:0] and determines whether the obtained training data is correct. Assume that the default read reference voltage of DQS signal generated by the flash module 150 is 0.2V, one step is 0.0078V, and the read reference voltage can be increased to up to 3 steps: The processing unit 134 executes at most 3 iterations, in which the new read reference voltages are 0.2078V, 0.2156V and 0.2234V. The predefined read time offset and the last read reference voltage, which make the flash I/F 139 can read the training data correctly, form the right-bound reference of the low-speed read eye diagram.

Subsequently, the processing unit 134 repeatedly executes a loop with the predefined read time offset until the training data cannot be read from the designated page in the flash module 150. In each iteration, the processing unit 134 decreases the current read reference voltage by one step to generate a new read reference voltage, and issues the set command to the flash module 150 through the flash I/F 139 to adjust the reference voltage of DQS signal generated by the I/F 151 of the flash module 150 to the new read reference voltage. Next, under the condition of the new read reference voltage and the predefined read time offset, the processing unit 134 obtains the training data on the data bus DQ[7:0] and determines whether the obtained training data is correct. Assume that the default read reference voltage of DQS signal generated by the flash module 150 is 0.2V, one step is 0.0042V, and the read reference voltage can be decreased to up to 5 steps: The processing unit 134 executes at most 5 iterations, in which the new read reference voltages are 0.1958V, 0.1916V, 0.1874V, and so on. The predefined read time offset and the last read reference voltage, which make the flash I/F 139 can read the training data correctly, form the left-bound reference of the low-speed read eye diagram.

Step S930: The center point of the low-speed read eye diagram is calculated according to the four bound references, and the read reference voltage and the read time offset closet to the center point of the low-speed read eye diagram are determined as the initial read reference voltage and the initial read time offset.

Step S940: The DQS signal generated by the flash module 150 is adjusted to provide with a high speed. In some embodiments, refer to FIG. 4, the processing unit 134 controls the flash I/F 139 to output a high-speed RE#signal to the flash module 150, so that the flash module 150 accordingly generates a high-speed DQS signal. The high speed can be any frequency higher than 1200 MHz.

Step S950: The search algorithm starting from the initial read reference voltage and the initial read time offset is executed to generate a high-speed read eye diagram including all combinations of reference voltages and time offsets that the flash I/F 139 can successfully read training data from the designated page of the flash module 150.

In an exemplary search algorithm, the processing unit 134 issues a set command to the flash module 150 through the flash I/F 139 for setting the reference voltage of DQS signal generated by the I/F 151 of the flash module 150 to the initial read reference voltage, and setting the initial read time offset to the DLL circuitry of the flash I/F 139 for fetching data on the data bus DQ[7:0].

Subsequently, the processing unit 134 repeatedly executes a loop with the initial read reference voltage until the training data cannot be read from the designated page in the flash module 150, or the generated new read time offset is higher than the upper limit. In each iteration, the processing unit 134 increases the current read time offset by one step to generate a new read time offset, and sets the new read time offset to the DLL circuitry of the flash I/F 139 for fetching data on the data bus DQ[7:0]. Next, under the condition of the initial read reference voltage and the new read time offset, the processing unit 134 obtains the training data on the data bus DQ[7:0] and determines whether the obtained training data is correct. Assume that the default frequency of DQS signal generated by the flash module 150 is 1400 MHz, one step is 4.5 ps, and the read time offset can be increased to up to 8 steps: The processing unit 134 executes at most 8 iterations, in which the new read time offsets are D_{r_init}+4.5 ps, D_{r_init}+9 ps, D_{r_init}+13.5 ps, and so on, where D_{r_init} represents the initial read time offset. The initial read reference voltage and the last read time offset, which make the flash I/F 139 can read the training data correctly, form the upper-bound reference of the high-speed read eye diagram.

Subsequently, the processing unit 134 repeatedly executes a loop with the initial read reference voltage until the training data cannot be read from the designated page in the flash module 150, or the generated new read time offset is lower than the lower limit. In each iteration, the processing unit 134 decreases the current read time offset by one step to generate a new read time offset, and sets the new read time offset to the DLL circuitry of the flash I/F 139 for fetching data on the data bus DQ[7:0]. Next, under the condition of the initial read reference voltage and the new read time offset, the processing unit 134 obtains the training data on the data bus DQ[7:0] and determines whether the obtained training data is correct. Assume that the default frequency of DQS signal generated by the flash module 150 is 1400 MHz, one step is 4.5 ps, and the read time offset can be decreased to up to 8 steps: The processing unit 134 executes at most 8 iterations, in which the new read time offsets are D_{r_init}−4.5 ps, D_{r_init}−9 ps, D_{r_init}−13.5 ps, and so on, where D_{r_init} represents the initial read time offset. The predefined read reference voltage and the last read time offset, which make the flash I/F 139 can read the training data correctly, form the lower-bound reference of the high-speed read eye diagram.

Subsequently, the processing unit 134 repeatedly executes a loop with the initial read time offset until the training data cannot be read from the designated page in the flash module 150, or the generated new read reference voltage is higher than the upper limit. In each iteration, the processing unit 134 increases the current read reference voltage by one step to generate a new read reference voltage, and issues the set command to the flash module 150 through the flash I/F 139 to adjust the reference voltage of DQS signal generated by the I/F 151 of the flash module 150 to the new read reference voltage. Next, under the condition of the new read reference voltage and the initial read time offset, the processing unit 134 obtains the training data on the data bus DQ[7:0] and determines whether the obtained training data is correct. Assume that one step is 0.0078V, and the read reference voltage can be increased to up to 3 steps: The processing unit 134 executes at most 3 iterations, in which the new read reference voltages are V_{r_init}+0.0078V, V_{r_init}+0.0156V and V_{r_init}+0.0234V, where V_{r_init} represents the initial read reference voltage. The initial read time offset and the last read reference voltage, which make the flash I/F 139 can read the training data correctly, form the right-bound reference of the high-speed read eye diagram.

Subsequently, the processing unit 134 repeatedly executes a loop with the initial read time offset until the training data cannot be read from the designated page in the flash module 150, or the generated new read reference voltage is lower than the lower limit. In each iteration, the processing unit 134 decreases the current read reference voltage by one step to generate a new read reference voltage, and issues the set command to the flash module 150 through the flash I/F 139 to adjust the reference voltage of DQS signal generated by the I/F 151 of the flash module 150 to the new read reference voltage. Next, under the condition of the new read reference voltage and the initial read time offset, the processing unit 134 obtains the training data on the data bus DQ[7:0] and determines whether the obtained training data is correct. Assume that one step is 0.0042V, and the read reference voltage can be decreased to up to 5 steps: The processing unit 134 executes at most 5 iterations, in which the new read reference voltages are V_{r_init}−0.0042V, V_{r_init}−0.0084V, V_{r_init}−0.0126V, and so on, where V_{r_init} represents the initial read reference voltage. The initial read time offset and the last read reference voltage, which make the flash I/F 139 can read the training data correctly, form the left-bound reference of the high-speed read eye diagram.

Step S960: The center point of the high-speed read eye diagram is calculated according to the four bound references, and the read reference voltage and the read time offset closet to the center point of the high-speed read eye diagram are determined as the calibrated read reference voltage and the calibrated read time offset.

Step S970: The calibrated read reference voltage and the calibrated read time offset are stored in non-volatile storage space of the device side, for example, the designated address of SRAM, or the designated system page in the flash module 150, so that the device side can set the flash module 150 and the flash I/F 139 to complete high-speed data reads in runtime accordingly.

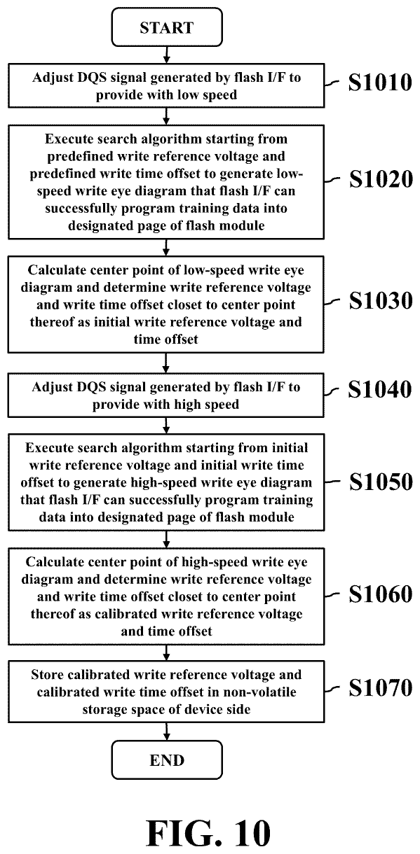

An embodiment of the invention introduces a method for calibrating signals with the flash I/F 139 for data writes, which is performed by the processing unit 134 when loading and executing calibration program code. Refer to the flowchart as shown in FIG. 10. Detailed descriptions are provided as follows:

Step S1010: The DQS signal generated by the flash I/F 139 is adjusted to provide with a low speed. In some embodiments, refer to FIG. 5, the processing unit 134 controls the flash I/F 139 to output a low-speed DQS signal. The low speed can be any frequency from 50 MHz to 200 MHz.

Step S1020: The search algorithm starting from the predefined write reference voltage (for example, 0.2V) and the predefined write time offset (for example, 0 ps) is executed to generate a low-speed write eye diagram including all combinations of reference voltages and time offsets that the flash I/F 139 can successfully program training data into the designated page of the flash module 150.

In an exemplary search algorithm, the processing unit 134 controls a transmitter in the flash I/F 139 for setting the reference voltage of output DQS signal to the predefined write reference voltage, and setting the predefined write time offset to a DLL circuitry of the flash I/F 139 for putting data on the data bus DQ[7:0]. The processing unit 134 issues the write command to the flash module 150 through the flash I/F 139 to instruct the flash module 150 to program training data into the designated page of the flash module, and then, outputting the training data to the flash module 150 through the data bus DQ[7:0] under the condition of the predefined write reference voltage and the predefined write time offset. The processing unit 134 issues the read command and the address to the flash module 150 through the flash I/F 139 to instruct the flash module 150 to read the training data from the designated page, and then, obtains the training data on the data bus DQ[7:0] under the condition of the predefined read reference voltage and the predefined time offset. The processing unit 134 determines whether the training data is correct. In some embodiments, if error bits included in the obtained training data can be corrected, then the obtained training data is judged as correct one. If the obtained training data is correct, let the search algorithm continue to execute. It is determined that the training data is successfully programmed into the designated page of the flash module 150 when the obtained training data is correct. Otherwise, it is determined that the training data is not successfully programmed into the designated page of the flash module 150. In very rare cases, the obtained training data is incorrect, indicating that there are critical manufacturing defects in the flash I/F 139 or the flash module 150, and the whole device side needs further inspection.

Subsequently, the processing unit 134 repeatedly executes a loop with the predefined write reference voltage until the training data cannot be programmed into the designated page in the flash module 150 correctly. In each iteration, the processing unit 134 increases the current write time offset by one step to generate a new write time offset, and sets the new write time offset to the DLL circuitry of the flash I/F 139 for putting data on the data bus DQ[7:0]. The processing unit 134 issues a write command to the flash module 150 through the flash I/F 139 to instruct the flash module 150 to program the training data into the designated page of the flash module 150, and then, under the condition of the predefined write reference voltage and the new write time offset, the processing unit 134 outputs the training data through the data bus DQ[7:0]. The processing unit 134 issues a read command to the flash module 150 through the flash I/F 139 to read data from the designated page of the flash module 150. The processing unit 134 determines whether the obtained training data is correct. If the obtained training data is correct, it means that the training data is successfully programmed into the designated page of the flash module 150. Otherwise, it means that the training data is not successfully programmed into the designated page of the flash module 150. Assume that the default frequency of DQS signal generated by the flash I/F 139 is 140 MHz, one step is 45 ps, and the write time offset can be increased to up to 8 steps: The processing unit 134 executes at most 8 iterations, in which the new write time offsets are 45 ps, 90 ps, 135 ps, and so on. The predefined write reference voltage and the last write time offset, which make the flash I/F 139 can write the training data correctly, form the upper-bound reference of the low-speed write eye diagram.

Subsequently, the processing unit 134 repeatedly executes a loop with the predefined write reference voltage until the training data cannot be programmed into the designated page in the flash module 150 correctly. In each iteration, the processing unit 134 decreases the current write time offset by one step to generate a new write time offset, and sets the new write time offset to the DLL circuitry of the flash I/F 139 for putting data on the data bus DQ[7:0]. The processing unit 134 issues a write command to the flash module 150 through the flash I/F 139 to instruct the flash module 150 to program the training data into the designated page of the flash module 150, and then, under the condition of the predefined write reference voltage and the new write time offset, the processing unit 134 outputs the training data through the data bus DQ[7:0]. The processing unit 134 issues a read command to the flash module 150 through the flash I/F 139 to read data from the designated page of the flash module 150. The processing unit 134 determines whether the obtained training data is correct. If the obtained training data is correct, it means that the training data is successfully programmed into the designated page of the flash module 150. Otherwise, it means that the training data is not successfully programmed into the designated page of the flash module 150. Assume that the default frequency of DQS signal generated by the flash I/F 139 is 140 MHz, one step is 45 ps, and the write time offset can be decreased to up to 8 steps: The processing unit 134 executes at most 8 iterations, in which the new write time offsets are −45 ps, −90 ps, −135 ps, and so on. The predefined write reference voltage and the last write time offset, which make the flash I/F 139 can write the training data correctly, form the lower-bound reference of the low-speed write eye diagram.

Subsequently, the processing unit 134 repeatedly executes a loop with the predefined write time offset until the training data cannot be programmed into the designated page in the flash module 150 correctly. In each iteration, the processing unit 134 increases the current write reference voltage by one step to generate a new write reference voltage, and controls the transmitter of the flash I/F 139 for setting the reference voltage of output DQS signal to the new write reference voltage. The processing unit 134 issues a write command to the flash module 150 through the flash I/F 139 to instruct the flash module 150 to program the training data into the designated page of the flash module 150, and then, under the condition of the new write reference voltage and the predefined write time offset, the processing unit 134 outputs the training data through the data bus DQ[7:0]. The processing unit 134 issues a read command to the flash module 150 through the flash I/F 139 to read data from the designated page of the flash module 150. The processing unit 134 determines whether the obtained training data is correct. If the obtained training data is correct, it means that the training data is successfully programmed into the designated page of the flash module 150. Otherwise, it means that the training data is not successfully programmed into the designated page of the flash module 150. Assume that the default write reference voltage of DQS signal generated by the flash I/F 139 is 0.2V, one step is 0.0078V, and the write reference voltage can be increased to up to 3 steps: The processing unit 134 executes at most 8 iterations, in which the new write reference voltages are 0.2078V, 0.2156V and 0.2234V. The predefined write time offset and the last write reference voltage, which make the flash I/F 139 can write the training data correctly, form the right-bound reference of the low-speed write eye diagram.

Subsequently, the processing unit 134 repeatedly executes a loop with the predefined write time offset until the training data cannot be programmed into the designated page in the flash module 150 correctly. In each iteration, the processing unit 134 decreases the current write reference voltage by one step to generate a new write reference voltage, and controls the transmitter of the flash I/F 139 for setting the reference voltage of output DQS signal to the new write reference voltage. The processing unit 134 issues a write command to the flash module 150 through the flash I/F 139 to instruct the flash module 150 to program the training data into the designated page of the flash module 150, and then, under the condition of the new write reference voltage and the predefined write time offset, the processing unit 134 outputs the training data through the data bus DQ[7:0]. The processing unit 134 issues a read command to the flash module 150 through the flash I/F 139 to read data from the designated page of the flash module 150. The processing unit 134 determines whether the obtained training data is correct. If the obtained training data is correct, it means that the training data is successfully programmed into the designated page of the flash module 150. Otherwise, it means that the training data is not successfully programmed into the designated page of the flash module 150. Assume that the default write reference voltage of DQS signal generated by the flash I/F 139 is 0.2V, one step is 0.0042V, and the write reference voltage can be decreased to up to 5 steps: The processing unit 134 executes at most 5 iterations, in which the new write reference voltages are 0.1958V, 0.1916V, 0.1874V, and so on. The predefined write time offset and the last write reference voltage, which make the flash I/F 139 can write the training data correctly, form the left-bound reference of the low-speed write eye diagram.

Step S1030: The center point of the low-speed write eye diagram is calculated according to the four bound references, and the write reference voltage and the write time offset closet to the center point of the low-speed write eye diagram are determined as the initial write reference voltage and the initial write time offset.

Step S1040: The DQS signal generated by the flash I/F 139 is adjusted to provide with a high speed. In some embodiments, refer to FIG. 5, the processing unit 134 controls the flash I/F 139 to output a high-speed DQS signal. The high speed can be any frequency higher than 1200 MHz.

Step S1050: The search algorithm starting from the initial write reference voltage and the initial write time offset is executed to generate a high-speed write eye diagram including all combinations of reference voltages and time offsets that the flash I/F 139 can successfully program training data into the designated page of the flash module 150.

In an exemplary search algorithm, the processing unit 134 controls a transmitter in the flash I/F 139 for setting the reference voltage of output DQS signal to the initial write reference voltage, and setting the initial write time offset to a DLL circuitry of the flash I/F 139 for putting data on the data bus DQ[7:0].

Subsequently, the processing unit 134 repeatedly executes a loop with the initial write reference voltage until the training data cannot be programmed into the designated page in the flash module 150 correctly, or the generated new write time offset is higher than the upper limit. In each iteration, the processing unit 134 increases the current write time offset by one step to generate a new write time offset, and sets the new write time offset to the DLL circuitry of the flash I/F 139 for putting data on the data bus DQ[7:0]. The processing unit 134 issues a write command to the flash module 150 through the flash I/F 139 to instruct the flash module 150 to program the training data into the designated page of the flash module 150, and then, under the condition of the initial write reference voltage and the new write time offset, the processing unit 134 outputs the training data through the data bus DQ[7:0]. The processing unit 134 issues a read command to the flash module 150 through the flash I/F 139 in the low-speed mode to read data from the designated page of the flash module 150. The processing unit 134 determines whether the obtained training data is correct. If the obtained training data is correct, it means that the training data is successfully programmed into the designated page of the flash module 150. Otherwise, it means that the training data is not successfully programmed into the designated page of the flash module 150. Assume that the default frequency of DQS signal generated by the flash I/F 139 is 1400 MHz, one step is 4.5 ps, and the write time offset can be increased to up to 8 steps: The processing unit 134 executes at most 8 iterations, in which the new write time offsets are D_{w_init}+4.5 ps, D_{w_init}+9ps, D_{w_init}+13.5 ps, and so on, where D_{w_init} represents the initial write time offset. The initial write reference voltage and the last write time offset, which make the flash I/F 139 can write the training data correctly, form the upper-bound reference of the high-speed write eye diagram.

Subsequently, the processing unit 134 repeatedly executes a loop with the initial write reference voltage until the training data cannot be programmed into the designated page in the flash module 150 correctly, or the generated new write time offset is lower than the lower limit. In each iteration, the processing unit 134 decreases the current write time offset by one step to generate a new write time offset, and sets the new write time offset to the DLL circuitry of the flash I/F 139 for putting data on the data bus DQ[7:0]. The processing unit 134 issues a write command to the flash module 150 through the flash I/F 139 to instruct the flash module 150 to program the training data into the designated page of the flash module 150, and then, under the condition of the initial write reference voltage and the new write time offset, the processing unit 134 outputs the training data through the data bus DQ[7:0]. The processing unit 134 issues a read command to the flash module 150 through the flash I/F 139 in the low-speed mode to read data from the designated page of the flash module 150. The processing unit 134 determines whether the obtained training data is correct. If the obtained training data is correct, it means that the training data is successfully programmed into the designated page of the flash module 150. Otherwise, it means that the training data is not successfully programmed into the designated page of the flash module 150. Assume that the default frequency of DQS signal generated by the flash I/F 139 is 1400 MHz, one step is 4.5 ps, and the write time offset can be increased to up to 8 steps: The processing unit 134 executes at most 8 iterations, in which the new write time offsets are D_{w_init}−4.5 ps, D_{w_init}−9 ps, D_{w_init}−13.5 ps, and so on, where D_{w_init} represents the initial write time offset. The initial write reference voltage and the last write time offset, which make the flash I/F 139 can write the training data correctly, form the lower-bound reference of the high-speed write eye diagram.

Subsequently, the processing unit 134 repeatedly executes a loop with the initial write time offset until the training data cannot be programmed into the designated page in the flash module 150 correctly, or the generated new write reference voltage is higher than the upper limit. In each iteration, the processing unit 134 increases the current write reference voltage by one step to generate a new write reference voltage, and controls the transmitter of the flash I/F 139 for setting the reference voltage of output DQS signal to the new write reference voltage. The processing unit 134 issues a write command to the flash module 150 through the flash I/F 139 to instruct the flash module 150 to program the training data into the designated page of the flash module 150, and then, under the condition of the new write reference voltage and the initial write time offset, the processing unit 134 outputs the training data through the data bus DQ[7:0]. The processing unit 134 issues a read command to the flash module 150 through the flash I/F 139 in the low-speed mode to read data from the designated page of the flash module 150. The processing unit 134 determines whether the obtained training data is correct. If the obtained training data is correct, it means that the training data is successfully programmed into the designated page of the flash module 150. Otherwise, it means that the training data is not successfully programmed into the designated page of the flash module 150. Assume that one step is 0.0078V, and the write reference voltage can be increased to up to 3 steps: The processing unit 134 executes at most 3 iterations, in which the new write reference voltages are V_{w_init}+0.0078V, V_{w_init}+0.0156V and V_{w_init}+0.0234V, where V_{w_init} represents the initial write reference voltage. The initial write time offset and the last write reference voltage, which make the flash I/F 139 can write the training data correctly, form the right-bound reference of the high-speed write eye diagram.

Subsequently, the processing unit 134 repeatedly executes a loop with the initial write time offset until the training data cannot be programmed into the designated page in the flash module 150 correctly, or the generated new write reference voltage is lower than the lower limit. In each iteration, the processing unit 134 decreases the current write reference voltage by one step to generate a new write reference voltage, and controls the transmitter of the flash I/F 139 for setting the reference voltage of output DQS signal to the new write reference voltage. The processing unit 134 issues a write command to the flash module 150 through the flash I/F 139 to instruct the flash module 150 to program the training data into the designated page of the flash module 150, and then, under the condition of the new write reference voltage and the initial write time offset, the processing unit 134 outputs the training data through the data bus DQ[7:0]. The processing unit 134 issues a read command to the flash module 150 through the flash I/F 139 in the low-speed mode to read data from the designated page of the flash module 150. The processing unit 134 determines whether the obtained training data is correct. If the obtained training data is correct, it means that the training data is successfully programmed into the designated page of the flash module 150. Otherwise, it means that the training data is not successfully programmed into the designated page of the flash module 150. Assume that one step is 0.0042V, and the write reference voltage can be increased to up to 5 steps: The processing unit 134 executes at most 5 iterations, in which the new write reference voltages are V_{w_init}−0.0042V, V_{w_init}−0.0084V, V_{w_init}−0.0126V, and so on, where V_{w_init} represents the initial write reference voltage. The initial write time offset and the last write reference voltage, which make the flash I/F 139 can write the training data correctly, form the left-bound reference of the high-speed write eye diagram.

Step S1060: The center point of the high-speed write eye diagram is calculated according to the four bound references, and the write reference voltage and the write time offset closet to the center point of the high-speed write eye diagram are determined as the calibrated write reference voltage and the calibrated write time offset.

Step S1070: The calibrated write reference voltage and the calibrated write time offset are stored in non-volatile storage space of the device side, for example, the designated address of SRAM, or the designated system page in the flash module 150, so that the device side can set the flash I/F 139 to complete high-speed data writes in runtime accordingly.

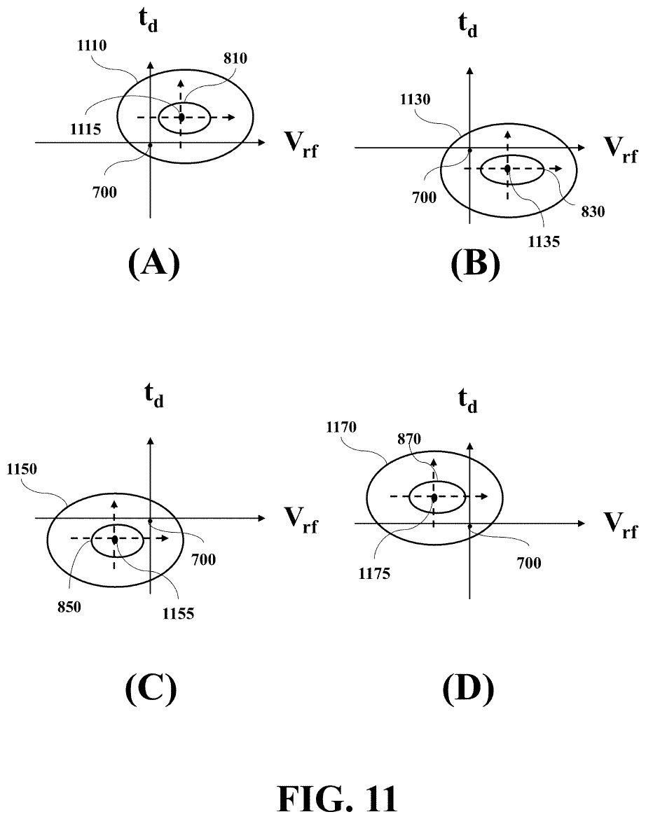

Refer to user cases as shown in FIG. 11. Part (A) of the eye diagram 810 as shown in FIG. 11 does not include the point 700 composed of the predefined reference voltage and the predefined time offset. With the two-stage search mechanism, the processing unit 134 obtains the center point 1115 of the low-speed eye diagram 1110 in the low-speed mode. Next, the high-speed eye diagram 810 is obtained in the high-speed mode according to the center point 1115, and the calibrated reference voltage and the calibrated time offset corresponding to the center point (not shown in FIG. 11) of the high-speed eye diagram 810 are obtained. Similarly, part (B) of FIG. 11 illustrates that the high-speed eye diagram 830 is obtained according to the center point 1135 of the low-speed eye diagram 1130 obtained in the low-speed mode, and then, the calibrated reference voltage and the calibrated time offset are obtained from the high-speed eye diagram 830. Part (C) of FIG. 11 illustrates that the high-speed eye diagram 850 is obtained according to the center point 1155 of the low-speed eye diagram 1150 obtained in the low-speed mode, and then, the calibrated reference voltage and the calibrated time offset are obtained from the high-speed eye diagram 850. Part (D) of FIG. 11 illustrates that the high-speed eye diagram 870 is obtained according to the center point 1175 of the low-speed eye diagram 1170 obtained in the low-speed mode, and then, the calibrated reference voltage and the calibrated time offset are obtained from the high-speed eye diagram 870.

Although the invention is illustrated and described herein with reference to specific embodiments, the invention is not intended to be limited to the details shown. Rather, various modifications may be made in the details within the scope and range of equivalents of the claims and without departing from the invention. It is to be understood that the above description is illustrative of the invention and is not to be construed as limiting the invention. Various modifications, applications and/or combinations of the embodiments may occur to those skilled in the art without departing from the scope of the invention as defined by the claims.

One having ordinary skill in the art will readily understand that the invention as discussed above may be practiced with hardware elements in configurations which are different than those which are disclosed. Therefore, although the invention has been described based upon these preferred embodiments, it would be apparent to those skilled in the art that certain modifications, variations, and alternative constructions would be apparent, while remaining within the scope of the invention.

The present invention will be described with respect to particular embodiments and with reference to certain drawings, but the invention is not limited thereto and is only limited by the claims. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent. ” etc.) The term “device” or “module” is not limited to one or a specific number of physical objects (such as one smartphone, one controller, one processing system and so on). As used herein, a device may be any electronic device with one or more parts that may implement at least some portions of the invention in this disclosure. While the description and examples use the term “device” or “module” to describe various aspects of this disclosure, the term “device” or “module” is not limited to a specific configuration, type, or number of objects. Additionally, the term “system” or “module” is not limited to multiple components or specific aspects. For example, a system may be implemented on one or more printed circuit boards or other substrates and may have movable or static components. While the description and examples use the term “system” to describe various aspects of the invention in this disclosure, the term “system” is not limited to a specific configuration, type, or number of objects.

Specific details are provided in the description above to provide a thorough understanding of the aspects and examples provided herein. However, it will be understood by one of ordinary skills in the art that the aspects may be practiced without these specific details. For clarity of explanation, in some instances the present technology may be presented as including individual functional blocks including functional blocks comprising devices, device components, steps or routines in a method embodied in software, or combinations of hardware and software. Additional components may be used other than those shown in the figures and/or described herein. For example, circuits, systems, networks, processes, and other components may be shown as components in block diagram form in order not to obscure the aspects in unnecessary detail. In other instances, well-known circuits, processes, algorithms, structures, and techniques may be shown without unnecessary detail in order to avoid obscuring the aspects.

Individual aspects may be described above as a process or method which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

Some or all of the aforementioned embodiments of the method of the invention may be implemented in a computer program such as a driver for a dedicated hardware, a Firmware Translation Layer (FTL) of a storage device, or others. Other types of programs may also be suitable, as previously explained. Since the implementation of the various embodiments of the present invention into a computer program can be achieved by the skilled person using his routine skills, such an implementation will not be discussed for reasons of brevity. The computer program implementing some or more embodiments of the method of the present invention may be stored on a suitable computer-readable data carrier, or may be located in a network server accessible via a network such as the Internet, or any other suitable carrier.

A computer-readable storage medium includes volatile and non-volatile, removable and non-removable media implemented in any method or technology for storage of information such as computer-readable instruction, data structures, program modules, or other data. A computer-readable storage medium includes, but is not limited to, RAM, ROM, EEPROM, flash memory or other memory, CD-ROM, digital versatile disks (DVD), Blue-ray disk or other optical storage, magnetic cassettes, magnetic tape, magnetic disk or other magnetic storage devices, or any other medium which can be used to store the desired information and may be accessed by an instruction execution system. Note that a computer-readable medium can be paper or other suitable medium upon which the program is printed, as the program can be electronically captured via, for instance, optical scanning of the paper or other suitable medium, then compiled, interpreted, or otherwise processed in a suitable manner, if necessary, and then stored in a computer memory.

The program code may be executed by a processor, which may include one or more processors, such as one or more digital signal processors (DSPs), general purpose microprocessors, an application specific integrated circuits (ASICs), field programmable logic arrays (FPGAs), or other equivalent integrated or discrete logic circuitry. Such a processor may be configured to perform any of the techniques described in this disclosure. A general-purpose processor may be a microprocessor; but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. Accordingly, the term “processor,” as used herein may refer to any of the foregoing structure, any combination of the foregoing structure, or any other structure or apparatus suitable for implementation of the techniques described herein.

The various illustrative logical blocks, modules, engines, circuits, and algorithm steps described in connection with the aspects disclosed herein may be implemented as electronic hardware, computer software, firmware, or combinations thereof. To clearly illustrate this interchangeability of hardware and software, various illustrative components, blocks, modules, engines, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present application.

Although the embodiment has been described as having specific elements in FIGS. 1-3, it should be noted that additional elements may be included to achieve better performance without departing from the spirit of the invention. Each element of FIGS. 1-3 is composed of various circuitries and arranged to operably perform the aforementioned operations. While the process flows described in FIGS. 9-10 include a number of operations that appear to occur in a specific order, it should be apparent that these processes can include more or fewer operations, which can be executed serially or in parallel (e.g., using parallel processors or a multi-threading environment).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for calibrating signals with a flash interface (I/F), performed by a processing unit of a flash controller, comprising:
directing a data transmission between the flash controller and a flash module to operate under a first speed;
executing a first search algorithm starting from a first reference voltage and a first time offset with driving of the flash I/F to generate a first eye diagram comprising combinations of reference voltages and time offsets that the flash I/F successfully completes the data transmission therebetween under the first speed, wherein the flash controller comprises the flash I/F, and the flash I/F is coupled to the flash module;
calculating a center point of the first eye diagram;
obtaining a second reference voltage and a second time offset closet to the center point of the first eye diagram;
directing the data transmission between the flash controller and the flash module to operate under a second speed, wherein the second speed is higher than the first speed;
executing a second search algorithm starting from the second reference voltage and the second time offset with driving of the flash I/F to generate a second eye diagram comprising combinations of reference voltages and time offsets that the flash I/F successfully completes the data transmission therebetween under the second speed;
calculating a center point of the second eye diagram;
obtaining a third reference voltage and a third time offset closet to the center point of the second eye diagram as a calibrated reference voltage and a calibrated time offset; and
storing the calibrated reference voltage and the calibrated time offset in nonvolatile space of a device side, thereby enabling the device side in runtime to configure the flash I/F accordingly for performing a high-speed data transmission,
wherein the device side comprises the flash controller and the flash module.

2. The method of claim 1, wherein the method is performed in a mass production process.

3. The method of claim 1, wherein the method is performed in a device initialization process by the device side during runtime.

4. The method of claim 1, wherein the first speed is any frequency from 50 MHz to 200 MHz, and the second speed is any frequency higher than 1200 MHz.

5. The method of claim 1, wherein the calibrated reference voltage represents a reference voltage of a data strobe signal transmitted from the flash module to the flash I/F, and the calibrated time offset represents a period of time before or after each rising edge or falling edge of the data strobe signal.

6. The method of claim 1, wherein the calibrated reference voltage represents a reference voltage of a data strobe signal transmitted from the flash I/F to the flash module, and the calibrated time offset represents a period of time before or after each rising edge or falling edge of the data strobe signal.

7. The method of claim 1, wherein the second speed is six times or more than the first speed.

8. A non-transitory computer-readable storage medium having stored therein program code that, when loaded and executed by a processing unit of a flash controller, causes the processing unit to:
direct a data transmission between the flash controller and a flash module to operate under a first speed;
execute a first search algorithm starting from a first reference voltage and a first time offset with driving of a flash interface (I/F) to generate a first eye diagram comprising combinations of reference voltages and time offsets that the flash I/F successfully completes the data transmission therebetween under the first speed, wherein the flash controller comprises the flash I/F, and the flash I/F is coupled to the flash module;
calculate a center point of the first eye diagram;
obtain a second reference voltage and a second time offset closet to the center point of the first eye diagram;
direct the data transmission between the flash controller and the flash module to operate under a second speed, wherein the second speed is higher than the first speed;
execute a second search algorithm starting from the second reference voltage and the second time offset with driving of the flash I/F to generate a second eye diagram comprising combinations of reference voltages and time offsets that the flash I/F successfully completes the data transmission therebetween under the second speed;
calculate a center point of the second eye diagram;
obtain a third reference voltage and a third time offset closet to the center point of the second eye diagram as a calibrated reference voltage and a calibrated time offset; and
store the calibrated reference voltage and the calibrated time offset in nonvolatile space of a device side, thereby enabling the device side in runtime to configure the flash I/F accordingly for performing a high-speed data transmission,
wherein the device side comprises the flash controller and the flash module.

9. The non-transitory computer-readable storage medium of claim 8, wherein the program code is executed in a mass production process.

10. The non-transitory computer-readable storage medium of claim 8, wherein the program code is executed in a device initialization process by the device side during runtime.

11. The non-transitory computer-readable storage medium of claim 8, wherein the calibrated reference voltage represents a reference voltage of a data strobe signal transmitted from the flash module to the flash I/F, and the calibrated time offset represents a period of time before or after each rising edge or falling edge of the data strobe signal.

12. The non-transitory computer-readable storage medium of claim 8, wherein the calibrated reference voltage represents a reference voltage of a data strobe signal transmitted from the flash I/F to the flash module, and the calibrated time offset represents a period of time before or after each rising edge or falling edge of the data strobe signal.

13. The non-transitory computer-readable storage medium of claim 8, wherein the second speed is six times or more than the first speed.

14. An apparatus for calibrating signals, comprising:
a flash interface (I/F), coupled to a flash module; and
a processing unit, coupled to the flash I/F, arranged operably to: direct a data transmission between a flash controller and the flash module to operate under a first speed; execute a first search algorithm starting from a first reference voltage and a first time offset with driving of the flash I/F to generate a first eye diagram comprising combinations of reference voltages and time offsets that the flash I/F successfully completes the data transmission therebetween under the first speed; calculate a center point of the first eye diagram; obtain a second reference voltage and a second time offset closet to the center point of the first eye diagram;
direct the data transmission between the flash controller and the flash module to operate under a second speed, wherein the second speed is higher than the first speed; execute a second search algorithm starting from the second reference voltage and the second time offset with driving of the flash I/F to generate a second eye diagram comprising combinations of reference voltages and time offsets that the flash I/F successfully completes the data transmission therebetween under the second speed; calculate a center point of the second eye diagram; obtain a third reference voltage and a third time offset closet to the center point of the second eye diagram as a calibrated reference voltage and a calibrated time offset; and store the calibrated reference voltage and the calibrated time offset in nonvolatile space of a device side, thereby enabling the device side in runtime to configure the flash I/F accordingly for performing a high-speed data transmission,
wherein the device side comprises the apparatus and the flash module.

15. The apparatus of claim 14, wherein the processing unit is arranged operably to: obtain the calibrated reference voltage and the calibrated time offset in a mass production process.

16. The apparatus of claim 14, wherein the processing unit is arranged operably to: obtain the calibrated reference voltage and the calibrated time offset in a device initialization process by the device side during runtime.

17. The apparatus of claim 14, wherein the first speed is any frequency from 50 MHz to 200 MHz, and the second speed is any frequency higher than 1200 MHz.

18. The apparatus of claim 14, wherein the calibrated reference voltage represents a reference voltage of a data strobe signal transmitted from the flash module to the flash I/F, and the calibrated time offset represents a period of time before or after each rising edge or falling edge of the data strobe signal.

19. The apparatus of claim 14, wherein the calibrated reference voltage represents a reference voltage of a data strobe signal transmitted from the flash I/F to the flash module, and the calibrated time offset represents a period of time before or after each rising edge or falling edge of the data strobe signal.

20. The apparatus of claim 14, wherein the second speed is six times or more than the first speed.
